(19) United States
(12) Patent Application Publication
(10) Pub. No.: US 2015/0076329 A1
(43) Pub. Date: Mar. 19, 2015

(54) SIGNAL FILTERING DEVICE

(71) Applicants: Nan-Jiun Yin, Hsin-Chu (TW); Lei-Chih Chang, Hsin-Chu (TW)

(72) Inventors: Nan-Jiun Yin, Hsin-Chu (TW); Lei-Chih Chang, Hsin-Chu (TW)

(73) Assignee: CORETRONIC CORPORATION, Hsin-Chu (TW)

(21) Appl. No.: 14/334,675

(22) Filed: Jul. 18, 2014

(30) Foreign Application Priority Data
Sep. 13, 2013 (CN) 201310418268.2

(51) Int. Cl. H03F 3/45; H03F 3/08

(52) U.S. Cl. CPC H03F 3/45076; H03F 3/08; H03F 2203/45531
USPC 250/214 A

(57) ABSTRACT

A signal filtering device is provided. A photoelectric conversion unit is used to convert a light signal into an electric signal, and an input signal adjusting unit is used to decrease a DC component of the electric signal flowing through a DC filtering unit and adjust an AC component of the electric signal.

### CROSS-REFERENCE TO RELATED APPLICATION

This application claims the priority benefit of China application serial no. 201310418268.2, filed on Sep. 13, 2013. The entirety of the above-mentioned patent application is hereby incorporated by reference herein and made a part of this specification.

### BACKGROUND

1. Technical Field

The invention relates to a signal filtering device. Particularly, the invention relates to a filtering device capable of filtering a direct current (DC) component of an electric signal and adjusting an alternating current (AC) component of the electric signal.

2. Related Art

A commonly used photo sensor senses lights by using a photo diode. However, a source of the light sensed by the photo diode is usually more than one, and besides light signals of an electronic system that applies the photo diode, sunlight and artificial lights such as fluorescent light, etc. are also be received.

U.S. Patent No. 20110181254 discloses an application of a photo diode, though there are still unresolved problems in electric signal processing.

### SUMMARY

The invention is directed to a signal filtering device preventing a transimpedance amplifier from entering a saturation state and enhancing a signal intensity of electric signal output by the transimpedance amplifier.

Additional aspects and advantages of the invention will be set forth in the description of the techniques disclosed in the invention.

To achieve one of or all aforementioned and other advantages, an embodiment of the invention provides a signal filtering device including a photoelectric conversion unit, a transimpedance amplifier, a feedback impedance unit, a direct current (DC) filtering unit, and an input signal adjusting unit. The photoelectric conversion unit is used for converting a light signal into an electric signal. A positive input terminal of the transimpedance amplifier is coupled to the ground. The feedback impedance unit is coupled between an output terminal and a negative input terminal of the transimpedance amplifier. The DC filtering unit is coupled between the photoelectric conversion unit and the negative input terminal of the transimpedance amplifier, and is used for filtering a DC component of the electric signal. The input signal adjusting unit is coupled to the photoelectric conversion unit, used for reducing the DC component of the electric signal flowing through the DC filtering unit, and used for adjusting an alternating current (AC) component of the electric signal.

According to an embodiment of the invention, the photoelectric conversion unit includes a photo diode. The photo diode has a cathode receiving an operating voltage and an anode coupled to the DC filtering unit.

According to an embodiment of the invention, the input signal adjusting unit includes an inductor. The inductor is coupled in series with the photoelectric conversion unit, and coupled to the ground.

According to an embodiment of the invention, the DC filtering unit includes a capacitor. The capacitor is coupled between the photoelectric conversion unit and the negative input terminal of the transimpedance amplifier.

According to an embodiment of the invention, the feedback impedance unit includes a resistor. The resistor is coupled between the output terminal and the negative input terminal of the transimpedance amplifier.

According to an embodiment of the invention, the signal filtering device further includes a voltage dividing unit. The voltage dividing unit is coupled between the photoelectric conversion unit and the ground, and used for dividing a voltage on a common node of the photoelectric conversion unit and the input signal adjusting unit, so as to generate a voltage-divided signal to the DC filtering unit.

According to an embodiment of the invention, the voltage dividing unit includes a first voltage dividing resistor and a second voltage dividing resistor. The first voltage dividing resistor and the second voltage dividing resistor are coupled in series between the ground and the common node of the photoelectric conversion unit and the input signal adjusting unit, and a common node of the first voltage dividing resistor and the second voltage dividing resistor is coupled to the DC filtering unit.

According to an embodiment of the invention, the light signal includes a modulated light signal and an ambient light signal.

According to an embodiment of the invention, the ambient light signal includes at least one of a sunlight signal and an artificial light signal.

According to an embodiment of the invention, the signal filtering device further includes a demodulation unit. The demodulation unit is coupled to the transimpedance amplifier, and used for demodulating a signal output by the transimpedance amplifier to generate a demodulated signal.

According to the above descriptions, the input signal adjusting unit is used to decrease the DC component of the electric signal flowing through the DC filtering unit, and adjust the AC component of the electric signal, so as to prevent the transimpendance amplifier from entering a saturation state and enhance signal intensity of the electric signal output by the transimpedance amplifier.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a signal filtering device according to an embodiment of the invention.

FIG. 2 is a schematic diagram of a signal filtering device according to another embodiment of the invention.

FIG. 3 is a schematic diagram of a signal filtering device according to another embodiment of the invention.

FIG. 4 is a schematic diagram of a signal filtering device according to another embodiment of the invention.

### DETAILED DESCRIPTION OF DISCLOSED EMBODIMENTS

The present invention will now be described more fully with reference to the accompanying drawings, in which exemplary embodiments of the invention are shown. The terms used herein such as “above”, “below”, “front”, “back”, “left” and “right” are for the purpose of describing directions in the figures only and are not intended to be limiting of the invention.

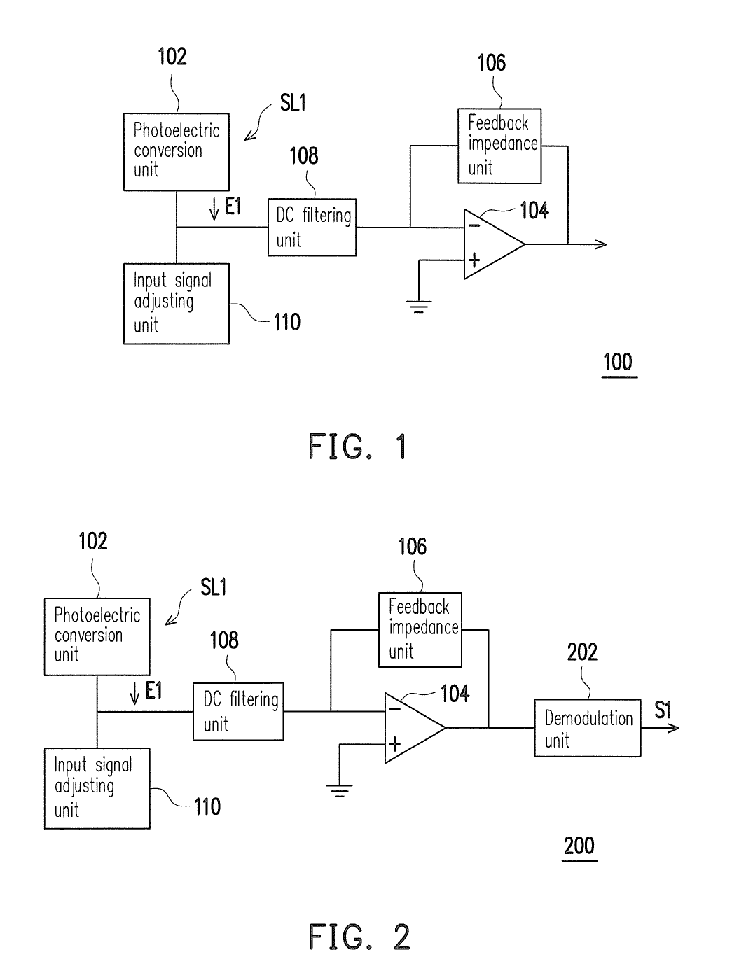

Referring to FIG. 1, the signal filtering device 100 includes a photoelectric conversion unit 102, a transimpedance amplifier 104, a feedback impedance unit 106, a DC filtering unit 108, and an input signal adjusting unit 110. The input signal adjusting unit 110 is coupled to the photoelectric conversion unit 102. The DC filtering unit 108 is coupled between the photoelectric conversion unit 102 and a negative input terminal of the transimpedance amplifier 104, and is coupled to a common node of the input signal adjusting unit 110, i.e. the DC filtering unit 108 is coupled between the negative input terminal of the transimpedance amplifier 104 and the common node of the photoelectric conversion unit 102 and the input signal adjusting unit 110. A positive input terminal of the transimpedance amplifier 104 is coupled to the ground. The feedback impedance unit 106 is coupled between the negative input terminal and an output terminal of the transimpedance amplifier 104. Moreover, the signal filtering device 110 may be a circuit, or an integrated circuit, etc., though the invention is not limited thereto.

The photoelectric conversion unit 102 receives a light signal SL1, and converts the light signal SL1 into an electric signal E1. The light signal SL1 may be an ambient light signal or a system light signal of an electronic apparatus (not shown) applying the signal filtering device 100. The ambient light signal, for example, includes at least one of a sunlight signal and an artificial light signal, and the artificial light signal is, for example, a light signal sent by a fluorescent lamp, an LED lamp or a conventional bulb, though the invention is not limited thereto. In the embodiment, the artificial light signal is the light signal sent by the fluorescent lamp. Moreover, the electric signal E1 corresponding to the light signal SL1 includes an electric signal corresponding to the system light signal and an electric signal corresponding to the ambient light signal, wherein the electric signal corresponding to the system light signal is an alternating current (AC) signal, the electric signal corresponding to the sunlight signal is a direct current (DC) signal, and the electric signal corresponding to the artificial light signal is an AC signal. The DC filtering unit 108 is used for filtering a DC component of the electric signal E1, for example, filtering the electric signal corresponding to the sunlight signal in the embodiment. The feedback impedance unit 106 and the transimpedance amplifier 104 are used for amplifying the DC component-filtered electric signal E1, so as to enhance signal intensity thereof.

Moreover, the input signal adjusting unit 110 adjusts a characteristic of the electric signal E1 output by the photoelectric conversion unit 102, i.e. decreases the DC component of the electric signal E1 flowing through the DC filtering unit 108, and adjust an AC component of the electric signal E1. In the embodiment, the input signal adjusting unit 110 may decrease a component (i.e. the DC component) of the electric signal corresponding to the sunlight signal and enhance a component (i.e. the AC component) of the electric signal corresponding to the system light signal and the artificial light signal. By decreasing the DC component of the electric signal, an input voltage received by the transimpedance amplifier 104 is avoided to be too large, so as to prevent the transimpedance amplifier 104 from entering the saturation state to output an incorrect signal. Moreover, the electric signal with the enhanced AC component may increase the intensity of the electric signal corresponding to the desired system light signal, so as to ensure correctly obtaining information carried by the system light signal.

Referring to FIG. 2, a difference between the signal filtering device 100 of the embodiment of FIG. 1 and the signal filtering device 200 of FIG. 2 is that the signal filtering device 200 further includes a demodulation unit 202 coupled to the output terminal of the transimpedance amplifier 104, and the system light signal of the embodiment is a modulated light signal. In the embodiment, the modulated light signal and the artificial light signal both presented as the AC signals are both output through the output terminal of the transimpedance amplifier 104 after being processed by the transimpedance amplifier 104, the feedback impedance unit 106, the DC filtering unit 108, and the input signal adjusting unit 110, etc., and detailed descriptions thereof have been described above, which are not repeated. The demodulation unit 202 demodulates the signal output by the transimpedance amplifier 104, so as to separate the electric signal corresponding to the modulated light signal from the signal output by the transimpedance amplifier 104 to generate a demodulated signal S1, such that a post-circuit may obtain the information carried by the modulated light signal to implement a post-processing.

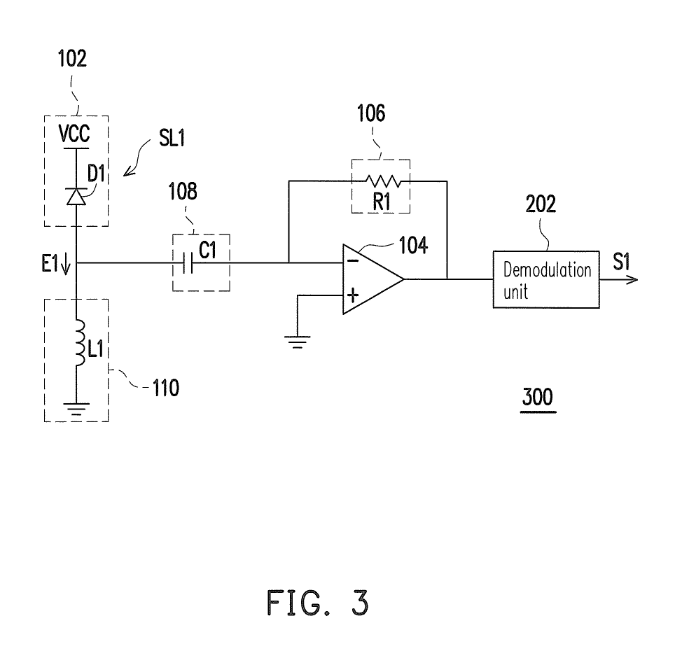

Referring to FIG. 3, implementation of the signal filtering device 200 of the embodiment of FIG. 2 may be shown in FIG. 3, in the signal filtering device 300 of FIG. 3, the photoelectric conversion unit 102 includes a photo diode D1, where a cathode of the photo diode D1 receives an operating voltage VCC, and an anode of the photo diode D1 is coupled to the DC filtering unit 108. In the embodiment, the DC filtering unit 108 includes a capacitor C1 coupled between the photoelectric conversion unit 102 and the negative input terminal of the transimpedance amplifier 104. In detail, the capacitor C1 of the embodiment is coupled between the anode of the photo diode D1 and the negative input terminal of the transimpedance amplifier 104. The feedback impedance unit 106 of the embodiment includes a resistor R1 coupled between the output terminal and the negative input terminal of the transimpedance amplifier 104. Moreover, the input signal adjusting unit 110 of the embodiment includes an inductor L1 coupled in series with the photoelectric conversion unit 102 and coupled to the ground. In detail, in the embodiment, the inductor L1 and the photo diode D1 are connected in series, and the inductor L1 is disposed between the photo diode D1 and the ground and is coupled between the anode of the photo diode D1 and the ground.

As that described above, the photo diode D1 is used for converting the light signal SL1 into the electric signal E1, the capacitor C1 is used for filtering the DC component in the electric signal E1, and the resistor R1 and the transimpedance amplifier 104 amplifies the DC-component-filtered electric signal E1 to facilitate the demodulation unit 202 performing demodulation, so as to output the correct demodulated signal S1. Moreover, the inductor L1 is used for reducing the DC component of the electric signal E1 flowing through the capacitor C1 and enhancing the AC component of the electric signal E1. In detail, an impedance of the inductor L1 includes a real part impedance R1 and an imaginary part impedance R2, wherein a DC signal voltage Vdc (not shown, which is described later) and an AC signal voltage Vac (not shown, which is described later) on the common node of the photo diode D1 and the inductor L1 respectively relate to the real part impedance R1 and the imaginary part impedance R2, which are respectively represented by following equations:

Vdc=I×R1 (1)

Vac=I×R2=I×2π×f×L (2)

I is a current value of the electric signal E1, f is a frequency of the electric signal E1, and L is an inductance value of the inductor L1. Namely, the DC signal voltage Vdc is determined by the real part impedance R1 of the inductor L1, and the AC signal voltage Vac is determined by the inductance value L of the inductor L1 and the frequency f of the electric signal E1. Since the inductor has a characteristic of low DC impedance, the real part impedance R1 is generally very low to be able to decrease a magnitude of the voltage output to the capacitor C1 by the photo diode D1, so as to prevent the capacitor C1 from receiving an excessively large voltage to damage the capacitor C1, and meanwhile the transimpedance amplifier 104 is prevented from entering the saturation state to output incorrect signal. Moreover, the AC signal voltage Vac is also related to the inductance value L of the inductor L1 and the frequency f of the electric signal E1. Namely, the output signal of the transimpedance amplifier 104 is not limited by the resistor R1 only. In this way, by adjusting the real part impedance R1 and the inductance value L of the inductor L1, the output signal of the transimpedance amplifier 104 may be more complied with an actual application requirement.

It should be noticed that implementations of the aforementioned photoelectric conversion unit 102, the DC filtering unit 108, the feedback impedance unit 106, and the input adjusting unit 110 are only an exemplary embodiment, and the actual application is not limited thereto. For example, the photoelectric conversion unit 102 may include more than one photo diode D1, the DC filtering unit 108 may include more than one capacitor C1, the feedback impedance unit 106 may include more than one resistor R1, and the input signal adjusting unit 110 may include more than one inductor L1. Namely, numbers of the photoelectric conversion units, the DC filtering units, the feedback impedance units, and the input signal adjusting units may be adjusted according to a design requirement, and different variations may be achieved by connecting the components thereof in series or parallel.

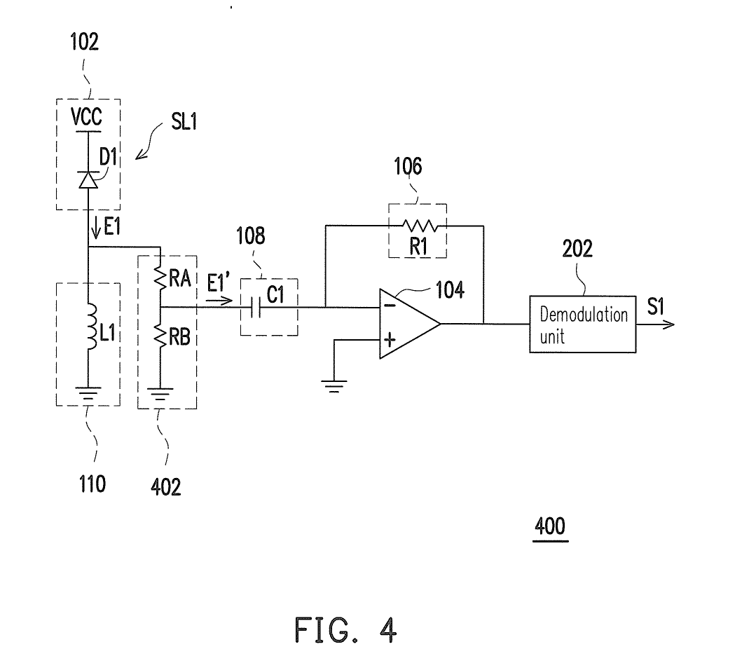

Referring to FIG. 4, a difference between the signal filtering device 400 of the embodiment and the signal filtering device 300 of FIG. 3 is that the signal filtering device 400 of the embodiment further includes a voltage dividing unit 402 coupled between the photoelectric conversion unit 102 and the ground. The voltage dividing unit 402 divides a voltage on the common node of the photoelectric conversion unit 102 and the input signal adjusting unit 110, so as to generate a voltage-divided signal to the DC filtering unit 108. In detail, the voltage dividing unit 402 is coupled between the ground and the common node of the photo diode D1 and the inductor L1, and the voltage dividing unit 402 includes a voltage dividing resistor RA and a voltage dividing resistor RB connected in series between the ground and the common node of the photoelectric conversion unit 102 and the input signal adjusting unit 110. Further, the voltage dividing resistor RA and the voltage dividing resistor RB are connected in series between the anode of the photo diode D1 and the ground, and a common node of the voltage dividing resistor RA and the voltage dividing resistor RB is coupled to the capacitor C1. The voltage dividing unit 402 divides a voltage on the common node of the photo diode D1 and the inductor L1, and generates a voltage-divided signal E1′ to the capacitor C1. In this way, the voltage value output to the capacitor C1 is further decreased so that a situation of the low DC impedance characteristic of the inductor L1 being unable to reduce the DC component in the electric signal E1 to result in not preventing damage of the capacitor C1 and/or not preventing the transimpedance amplifier 104 from entering the saturation state may be avoided.

In summary, in the embodiment of the invention, the input signal adjusting unit is used to decrease the DC component of the electric signal flowing through the DC filtering unit and the AC component of the electric signal is adjusted, so as to prevent the transimpendance amplifier from entering the saturation state and enhance signal intensity of the electric signal corresponding to the system light signal. In the embodiment of the invention, the voltage dividing unit may be used for dividing a voltage of the electric signal, so as to further reduce the voltage value of the electric signal and further prevent the transimpedance amplifier from entering the saturation state.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents. Moreover, any embodiment of or the claims of the invention is unnecessary to implement all advantages or features disclosed by the invention. Moreover, the abstract and the name of the invention are only used to assist patent searching, and are not used for limiting the claims of the invention. Moreover, “the first voltage dividing resistor”, “the second voltage dividing resistor”, etc. mentioned in the specification and the claims are merely used to name the elements and should not be regarded as limiting the upper or lower bound of the number of the components/devices.

What is claimed is:

1. A signal filtering device, comprising:
a photoelectric conversion unit, converting a light signal into an electric signal;
a transimpedance amplifier, having a positive input terminal coupled to a ground;
a feedback impedance unit, coupled between an output terminal of the transimpedance amplifier and a negative input terminal of the transimpedance amplifier;
a direct current (DC) filtering unit, coupled between the photoelectric conversion unit and the negative input terminal of the transimpedance amplifier, and filtering a DC component of the electric signal; and
an input signal adjusting unit, coupled to the photoelectric conversion unit, reducing the DC component of the electric signal flowing through the DC filtering unit, and adjusting an alternating current (AC) component of the electric signal.

2. The signal filtering device as claimed in claim 1, wherein the photoelectric conversion unit comprises:
a photo diode, having a cathode receiving an operating voltage and an anode coupled to the DC filtering unit.

3. The signal filtering device as claimed in claim 1, wherein the input signal adjusting unit comprises:
an inductor, coupled in series with the photoelectric conversion unit, and coupled to the ground.

4. The signal filtering device as claimed in claim 1, wherein the DC filtering unit comprises:
a capacitor, coupled between the photoelectric conversion unit and the negative input terminal of the transimpedance amplifier.

5. The signal filtering device as claimed in claim 1, wherein the feedback impedance unit comprises:
a resistor, coupled between the output terminal and the negative input terminal of the transimpedance amplifier.

6. The signal filtering device as claimed in claim 1, further comprising:
a voltage dividing unit, coupled between the photoelectric conversion unit and the ground, and dividing a voltage on a common node of the photoelectric conversion unit and the input signal adjusting unit, so as to generate a voltage-divided signal to the DC filtering unit.

7. The signal filtering device as claimed in claim 6, wherein the voltage dividing unit comprises:
a first voltage dividing resistor; and
a second voltage dividing resistor, the first voltage dividing resistor and the second voltage dividing resistor are coupled in series between the ground and the common node of the photoelectric conversion unit and the input signal adjusting unit, and a common node of the first voltage dividing resistor and the second voltage dividing resistor is coupled to the DC filtering unit.

8. The signal filtering device as claimed in claim 1, wherein the light signal comprises a modulated light signal and an ambient light signal.

9. The signal filtering device as claimed in claim 8, wherein the ambient light signal comprises at least one of a sunlight signal and an artificial light signal.

10. The signal filtering device as claimed in claim 8, further comprising:
a demodulation unit, coupled to the transimpedance amplifier, and demodulating a signal output by the transimpedance amplifier to generate a demodulated signal.
